(19) United States
(12) Patent Application Publication
(10) Pub. No.: US 2012/0061135 A1
(43) Pub. Date: Mar. 15, 2012

(54) COMPLIANT MULTILAYERED THERMALLY-CONDUCTIVE INTERFACE ASSEMBLIES HAVING EMI SHIELDING PROPERTIES

(75) Inventors: Richard F. Hill, Parkman, OH (US); Robert Michael Smythe, Ewing, NJ (US)

(73) Assignee: Laird Technologies, Inc., Chesterfield, MO (US)

(21) Appl. No.: 12/881,662

(22) Filed: Sep. 14, 2010

(51) Int. Cl. H05K 9/00; H01B 19/00

(52) U.S. Cl. 174/388; 29/887

(57) ABSTRACT

According to various aspects of the present disclosure, exemplary embodiments are disclosed of EMI shielding, thermally-conductive interface assemblies. In various exemplary embodiments, an EMI shielding, thermally-conductive interface assembly includes a thermal interface material and a sheet of shielding material, such as an electrically-conductive fabric, mesh, foil, etc. The sheet of shielding material may be embedded within the thermal interface material and/or be sandwiched between first and second layers of thermal interface material.

### FIELD

The present disclosure generally relates to compliant multilayered thermal interface materials and assemblies for establishing thermal-conducting heat paths from heat-generating components to a heat dissipating member or heat sink and providing electromagnetic interference (EMI) shielding.

### BACKGROUND

This section provides background information related to the present disclosure which is not necessarily prior art.

Electronic components, such as semiconductors, transistors, etc., typically have pre-designed temperatures at which the electronic components optimally operate. Ideally, the pre-designed temperatures approximate the temperature of the surrounding air. But the operation of electronic components generates heat which, if not removed, will cause the electronic component to operate at temperatures significantly higher than its normal or desirable operating temperature. Such excessive temperatures may adversely affect the operating characteristics, lifetime, and/or reliability of the electronic component and the operation of the associated device.

To avoid or at least reduce the adverse operating characteristics from the heat generation, the heat should be removed, for example, by conducting the heat from the operating electronic component to a heat sink. The heat sink may then be cooled by conventional convection and/or radiation techniques. During conduction, the heat may pass from the operating electronic component to the heat sink either by direct surface contact between the electronic component and heat sink and/or by contact of the electronic component and heat sink surfaces through an intermediate medium or thermal interface material. The thermal interface material may be used to fill the gap between thermal transfer surfaces, in order to increase thermal transfer efficiency as compared to having the gap filled with air, which is a relatively poor thermal conductor. In some devices, an electrical insulator may also be placed between the electronic component and the heat sink, in many cases this is the thermal interface material itself.

Electronic equipment often generates electromagnetic signals in one portion of the electronic equipment that may radiate to and interfere with another portion of the electronic equipment and/or other electronic equipment. This electromagnetic interference (EMI) can cause degradation or complete loss of important signals, thereby rendering the electronic equipment inefficient or inoperable. To reduce the adverse effects of EMI, shielding may be interposed between the two portions of the electronic circuitry for absorbing and/or reflecting EMI energy. This shielding may take the form of a wall or a complete enclosure and may be placed around the portion of the electronic circuit generating the electromagnetic signal and/or may be placed around the portion of the electronic circuit that is susceptible to the electromagnetic signal. For example, electronic circuits or components of a printed circuit board (PCB) are often enclosed with shields to localize EMI within its source, and to insulate other devices proximal to the EMI source.

As used herein, the term electromagnetic interference (EMI) should be considered to generally include and refer to both electromagnetic interference (EMI) and radio frequency interference (RFI) emissions, and the term “electromagnetic” should be considered to generally include and refer to both electromagnetic and radio frequency from external sources and internal sources. Accordingly, the term shielding (as used herein) generally includes and refers to both EMI shielding and RFI shielding, for example, to prevent (or at least reduce) ingress and egress of EMI and RFI relative to a housing, enclosure, etc. in which electronic equipment is disposed.

### SUMMARY

This section provides a general summary of the disclosure, and is not a comprehensive disclosure of its full scope or all of its features.

According to various aspects of the present disclosure, exemplary embodiments are disclosed of EMI shielding, thermally-conductive interface assemblies. In various exemplary embodiments, an EMI shielding, thermally-conductive interface assembly includes a thermal interface material and a sheet of shielding material, such as an electrically-conductive fabric, mesh, foil, flexible graphite sheet, etc. The sheet of shielding material may be embedded within the thermal interface material and/or be sandwiched between first and second layers of thermal interface material.

Additional aspects provide methods relating to EMI shielding, thermally-conductive interface assemblies, such as methods of using and/or making EMI, shielding thermally-conductive interface assemblies. In an exemplary embodiment, a method generally includes positioning an assembly, which comprises a sheet of shielding material embedded in a thermal interface material, such that a thermally-conductive heat path is defined from at least one heat generating component through the thermal interface material and the sheet of shielding material, and such that transmission of EMI to and/or from the at least one heat generating component is restricted.

Another exemplary embodiment provides a method for making an EMI shielding, thermally-conductive interface assembly having an upper surface and a lower surface. In this example, the method generally includes applying thermal interface material to an electrically-conductive fabric having a plurality of interstices such that the electrically-conductive fabric is embedded in the thermal interface material and such that at least a portion of the thermal interface material is disposed within at least one of the plurality of interstices to provide a thermally-conductive path between the upper surface and the lower surface and restrict transmission of EMI through the thermally-conductive interface assembly.

Further aspects and features of the present disclosure will become apparent from the detailed description provided hereinafter. In addition, any one or more aspects of the present disclosure may be implemented individually or in any combination with any one or more of the other aspects of the present disclosure. It should be understood that the detailed description and specific examples, while indicating exemplary embodiments of the present disclosure, are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an isometric exploded view of a thermally-conductive interface assembly including a sheet (e.g., electrically-conductive fabric, mesh, foil, perforated foil, metal layer, flexible graphite sheet, etc.) of shielding material aligned for attachment to a thermal interface material according to exemplary embodiments;

FIG. 2 is a cross-sectional view of an exemplary embodiment of a thermally-conductive interface assembly in which a sheet of shielding material is attached to a thermal interface material according to exemplary embodiments;

FIG. 3 is a cross-sectional view of another exemplary embodiment of a thermally-conductive interface assembly in which a sheet of shielding material is embedded in a thermal interface material according to exemplary embodiments;

FIG. 4 is a close-up view of a electrically-conductive fabric illustrating fibers of the electrically-conductive fabric and the interstices between the illustrated fibers according to exemplary embodiments;

FIG. 5 is a cross-sectional view of another exemplary embodiment of a thermally-conductive interface assembly in which a sheet of shielding material is fully embedded or encapsulated in a thermal interface material according to exemplary embodiments;

FIG. 6 is an isometric exploded view of a thermally-conductive interface assembly including a sheet of shielding material and two layers of thermal interface material according to exemplary embodiments;

FIG. 7 is a cross-sectional view of another exemplary embodiment of a thermally-conductive interface assembly in which a sheet of shielding material is fully embedded or encapsulated in a thermal interface material by being sandwiched between two layers of thermal interface material according to exemplary embodiments;

FIG. 8 is a cross-sectional view of a circuit board having an electronic component and a thermally-conductive interface assembly including a sheet of shielding material, where the thermally-conductive interface assembly is wrapped around and contacts substantially all of a top and sides of the electronic component according to exemplary embodiments; and

FIG. 9 is a cross-sectional view of a circuit board having an electronic component, a thermally-conductive interface assembly including a sheet of shielding material, and a heat sink, where the thermally-conductive interface assembly is draped over a top of the electronic component and surrounds the sides of the electronic component without substantially contacting the sides of the electronic component according to exemplary embodiments.

Corresponding reference numerals indicate corresponding parts throughout the several views of the drawings.

### DETAILED DESCRIPTION

The following description is merely exemplary in nature and is in no way intended to limit the present disclosure, application, or uses.

Thermal interface materials have been used between heat-generating components and heat sinks to establish heat-conduction paths therebetween. EMI shielding materials have been used to restrict transmission of EMI to and/or from electronic components. As recognized by the inventors hereof, however, such electronic components to be shielded by EMI shielding materials are also heat generating components with which it may be also desirable to use a thermal interface material. Accordingly, two separate products are often utilized with a component or group of components, i.e., an EMI shielding material and a thermal interface material resulting in higher costs for materials, extra design work, additional tooling, etc.

Because the inventors hereof recognized that separate thermal interface materials and EMI shielding materials are often used in conjunction with the same electronic component, the inventors have disclosed herein various exemplary embodiments of EMI shielding, thermally-conductive interface assemblies including both thermal transfer and EMI shielding properties. In various exemplary embodiments, the inventors hereof have integrated EMI shielding within a thermal gap filler material, which eliminates the need for two separate EMI shielding and thermal interface materials and reduces costs and tooling. In accordance with exemplary embodiments disclosed herein, an EMI thermally-conductive assembly may be provided or comprise a one-shielding, piece, flexible, and conformable product that is relatively easily manufactured, applied, and/or installed.

In various exemplary embodiments, EMI shielding, thermally-conductive interface assemblies disclosed herein include a sheet of shielding material and one or more layers of soft or compliant thermal interface material (e.g., thermal interface material disposed on at least one side or on opposite sides of a sheet of shielding material, etc.). The sheet of shielding material may comprise one or more of an electrically-conductive (e.g., metalized, etc.) fabric, an electrically-conductive mesh, a metal foil, a metal foil having one or more openings therethrough, a thin metal layer, a thin metal layer having one or more openings therethrough, a flexible graphite sheet, etc.

In an exemplary embodiment, an EMI shielding, thermally-conductive interface assembly generally includes a sheet of shielding material embedded within or encapsulated within a soft or compliant thermal interface material. For example, a sheet of shielding material may be encapsulated within, embedded within, or sandwiched between first and second layers of a thermal interface material (e.g., thermal gap filler, etc.). This particular embodiment may provide good (or at least sufficient) compliability or softness, heat transfer properties of the thermal gap filler, and offering EMI protection.

The shielding material may be any shielding material that is flexible enough to be used in a thermally-conductive interface assembly and capable of being incorporated in a thermally-conductive interface assembly. In various exemplary embodiments, the shielding material may be an electrically-conductive fabric, such as nylon ripstop (NRS) fabric coated with nickel and/or copper, nickel-plated polyester or taffeta fabric, etc. Or, for example, the shielding material may comprise a nickel/copper plated knit mesh, metal foil (e.g., nickel foil, etc.), metal mesh (e.g., nickel mesh, etc.), metal foil having one or more openings therethrough, a thin metal layer, a thin metal layer having one or more openings therethrough, etc.

As another example, the shielding material may comprise a flexible graphite sheet. In these latter embodiments, the flexible graphite sheet may comprise particles of intercalated and exfoliated graphite flakes formed into a flexible graphite sheet, which may have one or more perforations or it may have no perforations. In any one or more of the embodiments disclosed herein that include a flexible graphite sheet, the flexible graphite sheet may include compressed particles of exfoliated graphite, formed from intercalating and exfoliating graphite flakes, such as eGraf™ commercially available from Advanced Energy Technology Inc. of Lakewood, Ohio. A flexible graphite sheet may be made from one or more of the materials (e.g., graphite, flexible graphite sheet, exfoliated graphite, etc.) disclosed in any one or more of U.S. Pat. No. 6,482,520, U.S. Pat. No. 6,503,626, U.S. Pat. No. 6,841,250, U.S. Pat. No. 7,138,029, U.S. Pat. No. 7,150,914, U.S. Pat. No. 7,160,619, U.S. Pat. No. 7,276,273, U.S. Pat. No. 7,303,820, U.S. Patent Application Publication 2007/0042188, U.S. Patent Application Publication 2007/0077434, U.S. Pat. No. 7,292,441, U.S. Pat. No. 7,306,847, and/or U.S. Pat. No. 3,404,061. In embodiments that include a sheet formed from intercalating and exfoliating graphite, the graphite may be processed into a sheet having a thickness within a range of about 0.005 inches to about 0.020 inches. For example, some embodiments include a sheet having a thickness of 0.005 inches, or 0.020 inches, or a thickness greater than 0.005 inches but less than 0.020 inches. Further embodiments may include a sheet having a thickness less than 0.005 inches or greater than 0.020 inches. Plus, other materials and thicknesses may be used for a sheet in addition to or as an alternative to graphite. For example, some embodiments may include a relatively thin sheet of copper and/or or aluminum materials, which may have a comparable flexibility to a graphite sheet.

In alternative embodiments, the shielding material may be relatively rigid and/or not be highly flexible. In such embodiments, the shielding material may be encapsulated, embedded, etc. within thermal interface material (e.g., gap filler, etc.) that is more flexible, deformable, soft, compliable, etc. than the shielding material. The thermal interface material may thus provide sufficient flexibility, deformability, deflection, and/or softness to the thermally-conductive interface assembly despite the less flexible or relatively rigid shielding material.

EMI shielding, thermally-conductive interface assemblies disclosed herein include one or more outer layers of soft thermal interface materials that are relatively flexible, soft, and/or thin, for example, for good conformance with a mating surface. This, in turn, may help lower thermal impendence as thermal impedance depends, at least in part, upon the degree of effective surface area contact therebetween. The ability to conform to a mating surface tends to be important as the surfaces of a heat sink and/or a heat-generating component are typically not perfectly flat and/or smooth, such that air gaps or spaces (air being a relatively poor thermal conductor) tend to appear between the irregular mating surfaces (e.g., a non-uniform surface that is not flat or continuous, a non-flat surface, curved surface, uneven surface, surface without symmetry, even shape, or formal arrangement, etc.). Therefore, removal of air spaces may thus also help lower the heat-conducting path's thermal impedance and increases the path's thermal conductivity, thereby enhancing the conducting of heat along the path. Furthermore, the flexible, soft, and/or thin nature of the thermal interface material(s) and the flexible nature of the shielding material permit the thermally-conductive assemblies to be draped, wrapped, etc. around a component. Surrounding a component (e.g., by draping, wrapping, etc. with a thermally-conductive assembly) improves the EMI shielding provided by the thermally-conductive assembly.

In various exemplary embodiments, an EMI shielding, thermally-conductive interface assembly as disclosed herein may be utilized in conjunction with a printed circuit board, power amplifier, central processing unit, graphics processing unit, memory module, or other component that may be heat-generating, EMI generating, and/or EMI susceptible component. For example, an EMI shielding, thermally-conductive interface assembly may be positioned, sandwiched, or installed between a heat sink and one or more heat-generating components or heat sources (e.g., printed circuit board assembly, power amplifier, central processing unit, graphics processing unit, memory module, other heat-generating component, etc.), such that the EMI shielding, thermally-conductive interface assembly is in contact with or against a surface of the heat-generating component, whereby a thermally-conducting heat path is defined from the heat-generating component to the thermally-conductive interface assembly and then to the heat sink. Furthermore, an EMI shielding, thermally-conductive interface assembly may be draped, wrapped, etc. around such a component (e.g., printed circuit board assembly, power amplifier, central processing unit, graphics processing unit, memory module, other heat-generating component, etc.), such that the EMI shielding, thermally-conductive interface assembly surrounds the component, whereby transmission of EMI to and/or from the component is restricted.

As disclosed herein, various embodiments include shielding material encapsulated or embedded (e.g., partially embedded, fully embedded, etc.) in a layer of thermal interface material and/or sandwiched between layers of thermal interface material. The shielding material may include interstices (also sometimes referred to as holes, pores, openings, gaps, apertures, etc.) between the elements from which the shielding material is constructed. For example, in embodiments where the shielding material is an electrically-conductive fabric, there are interstices between the threads from which the fabric is weaved, knitted, etc. In some embodiments, some of the thermal interface material is disposed within and/or passes completely through such interstices. In embodiments where the electrically-conductive fabric is fully embedded within a thermal interface material, thermal interface material on one side of the fabric may be bonded to thermal interface material on a second side of the fabric through the interstices. Such bonding may be present when the electrically-conductive fabric is fully embedded in a thermal interface material or when the electrically-conductive fabric is sandwiched between two layers of thermal interface material. This bond helps keep the sandwich or stack of materials together mechanically as well as providing heat transfer through the electrically-conductive fabric.

Thermal interface material (e.g., a thermally-conductive polymer, etc.) may be applied to a single side of the shielding material and then the shielding material with the polymer thereon may be ran through a pair of rolls or rollers. The polymer may be allowed to cure in some embodiments. In other embodiments, a putty may be applied to one or both sides of the shielding material. The putty may be already cured and pliable such that the putty doesn't have to cure after being applied to the shielding material. In embodiments in which the thermally-conductive interface assembly includes upper and lower layers of thermal interface material, polymer may then be applied to the other side of the shielding material. The shielding material with the polymer on the second side (and the cured polymer on the first side) may again be ran through a pair of rolls or rollers. The polymer on the second side is then also be allowed to cure. As another example, polymer may be applied to both sides of the shielding material, such that the shielding material with the polymer on both sides is ran through a pair of rollers or rolls. After the rolling process, the polymer on both sides is then allowed to cure. In various embodiments, a Mylar protective liner(s) may be disposed over the polymer, for example, to protect the rolls or rollers from the polymer. After curing the polymer, the Mylar protective liner(s) may be released and removed.

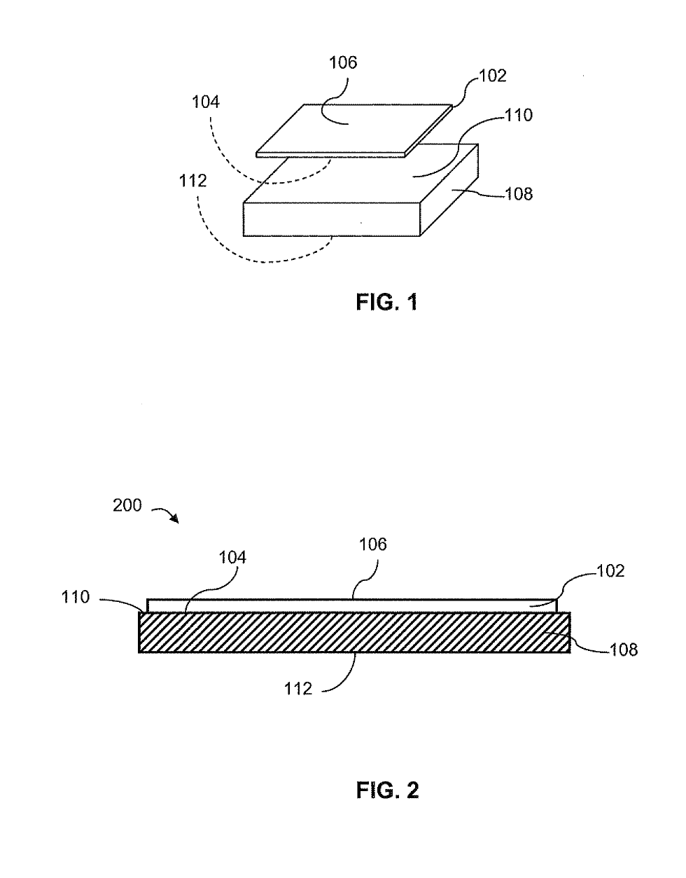

Referring now to FIG. 1, there is shown, in exploded view, the components that may be combined into various exemplary embodiments of an EMI shielding, thermally-conductive interface assembly embodying one or more aspects of the present disclosure. As shown in the exploded view in FIG. 1, an EMI shielding, thermally-conductive interface assembly may include a sheet of shielding material 102 (e.g., electrically-conductive fabric, etc.) having first and second sides 104, 106. The EMI shielding, thermally-conductive interface assembly includes a relatively soft thermal interface material 108 (e.g., gap filler, thermally-conductive polymer, thermally-conductive polymer with fillers therein, other suitable thermal interface materials such as those disclosed hereinafter, etc.). The thermal interface material 108 has an upper surface 110 and a lower surface 112. As used herein, the term “sheet” includes within its meaning a shielding materials in the form of flexible webs, strips, papers, tapes, foils, films, mats, rolls, or the like. The term “sheet” includes within its meaning substantially flat material or stock of any length and width.

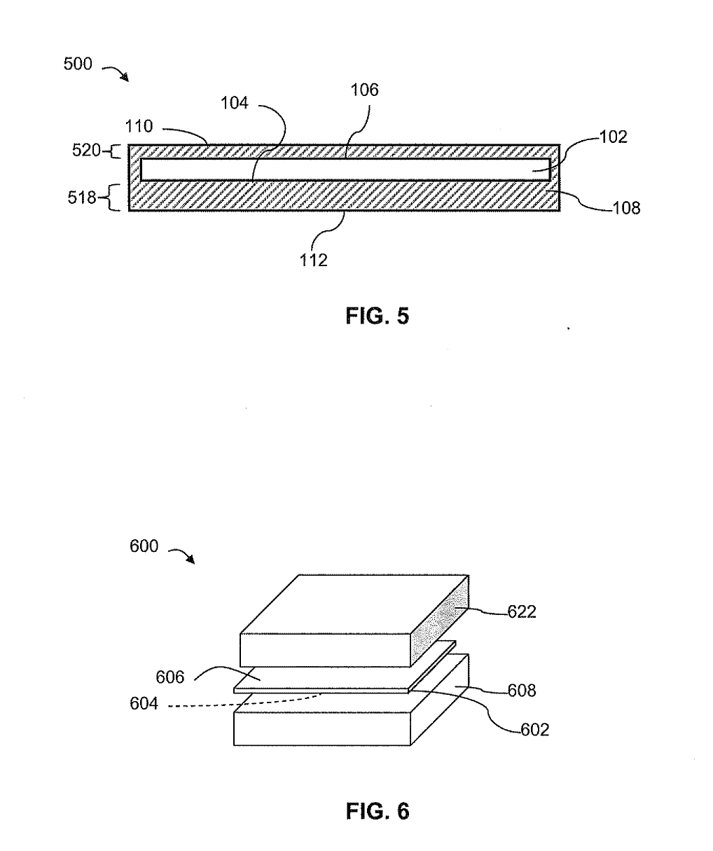

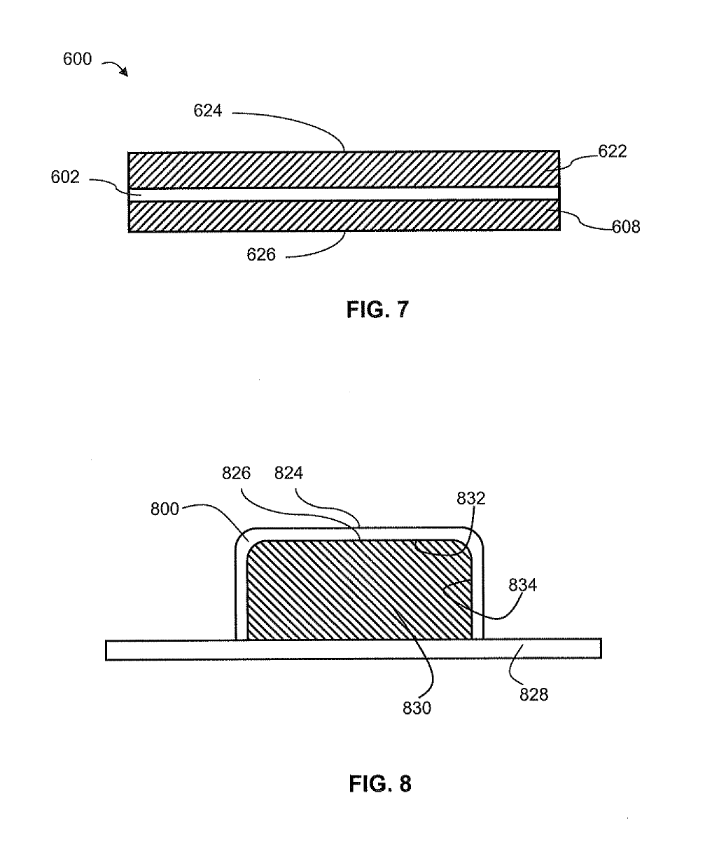

FIG. 2 illustrates one exemplary EMI shielding, thermally-conductive interface assembly 200 constructed of the thermal interface material 108 and sheet of shielding material 102. In this example embodiment, the sheet of shielding material 102 is disposed (e.g., bonded, mechanically attached, fastened, etc.) relative to the thermal interface material 108 with the first side 104 of the sheet of shielding material 102 adjacent the upper surface 110 of the thermal interface material 108. Alternative embodiments, however, may include the thermal interface material 108 on both sides 104 and 106 (e.g., assembly 500 in FIG. 5, assembly 600 in FIGS. 6 and 7, etc.) of the sheet of shielding material 102.

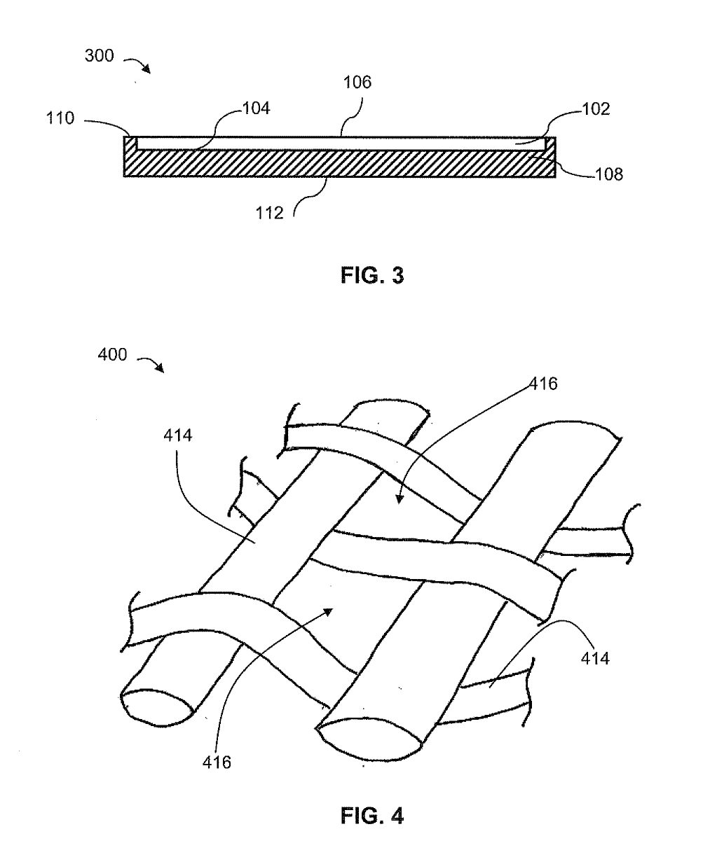

FIG. 3 illustrates another example EMI shielding, thermally-conductive interface assembly 300 including thermal interface material 108 and sheet of shielding material 102. In this embodiment, the sheet of shielding material 102 is embedded in the thermal interface material 108. The first side 104 of the sheet of shielding material 102 is below the upper surface 110. In the illustrated assembly 300, the second side of the sheet of shielding material 102 is substantially in the same plane as the upper surface 110 of the thermal interface material 108. In other embodiments, however, the second side of the sheet of shielding material 102 may protrude above or be below the upper surface 110 of the thermal interface material 108.

The sheet of shielding material 102 may include interstices (e.g., holes, apertures, pores, openings, voids, etc.) between the elements from which it is made. For example, the sheet of shielding material 102 may be an electrically-conductive fabric, such as the fabric 400 illustrated (in extreme close-up) in FIG. 4. As illustrated in FIG. 4, the electrically-conductive fabric 400 is made of a plurality of fibers 414 (e.g., thread, yarn, wire, filament, etc. which are woven, knitted, etc. together to form a fabric). Between the fibers 414 in the fabric 400 are a plurality of interstices 416.

In some embodiments, the thermal interface material 108 may be disposed (e.g., impregnated, etc.) within and/or through interstices in the sheet of shielding material 102. This may be realized by varying the thickness (e.g., viscosity, particle size, etc.) of the thermal interface material 108, selecting a sheet of shielding material 102 with interstices large enough (e.g., porous enough, etc.) for the thermal interface material 108 to pass through during manufacture, and/or combining the sheet of shielding material 102 and the thermal interface material 108 when the thermal interface material 108 is less cured, set, etc. The size of interstices in an electrically-conductive fabric may vary, for example, by type of fiber, quality of manufacture, type of fabric, method of manufacture (e.g., knitting versus weaving, etc.), fiber count per defined area, tightness of a weave, etc.

In an exemplary embodiment, the sheet of shielding material (e.g., 102, etc.) comprises an electrically-conductive fabric (e.g., 400, etc.) having a plurality of interstices (e.g., 416, etc.). In this example, the electrically-conductive fabric is impregnated with the thermal interface material (e.g., 108, etc.), such that the thermal interface material is within the interstices. The thermal interface material may remain confined within the interstices, such that the resulting EMI shielding, thermally-conductive interface assembly may be relatively very thin (e.g., de minimis or relatively insignificant thickness, etc.). Or, for example, the thermal interface material may pass completely through the interstices and form top and bottom layers of thermal interface material on the electrically-conductive fabric.

In other exemplary embodiments, the sheet of EMI shielding material (e.g., 102, etc.) may be configured (e.g., rolled, formed, etc.) to have a generally hollow or tubular configuration (e.g., be shaped as a tube, etc.). Thermal interface material (e.g., 108, etc.) may be disposed within the hollow interior portion of the EMI shielding material. In one particular embodiment, an electrically-conductive fabric (e.g., 400, etc.) is formed into a tube, which tube includes or is filled with the thermal interface material. In such embodiment, the EMI shielding, thermally-conductive interface material may comprise a fabric over thermal interface material gasket, etc.

Referring back to FIG. 3, the EMI shielding, thermally-conductive interface assembly 300 may or may not include thermal interface material 108 within interstices of the sheet of shielding material 102. If the interstices in the sheet of shielding material 102 are small enough and/or the thermal interface material 108 is thick enough, no thermal interface material 108 may pass through the interstices. Conversely, if interstices in the sheet of shielding material 102 are large enough and/or the thermal interface material 108 is thin enough (again, in the sense of particle size, viscosity, etc.), thermal interface material 108 may pass into and/or through the interstices. Both such examples may be appropriate for various uses.

FIG. 5 illustrates another example EMI shielding, thermally-conductive interface assembly 500 including the sheet of shielding material 102 fully embedded within the thermal interface material 108. Both of the first and second sides 104, 106 of the sheet of shielding material 102 are below the plane of the upper surface of the thermal interface material 108. Typically, (although not necessarily always) in such an embodiment at least a portion of the thermal interface material 108 is disposed in interstices in the sheet of shielding material 102. In the example EMI shielding, thermally-conductive interface assembly 500, there are two layers of thermal interface material 108 around the sheet of shielding material 102. First and second layers 518, 520 of the thermal interface material 108 are respectively disposed adjacent the first and second side 104, 106 of the sheet of shielding material 102.

The first and second layers 518, 520 are bonded together to provide a thermal pathway for heat transfer through the EMI shielding, thermally-conductive interface assembly 500. This connection may occur at locations where the first and second layers 518, 520 directly contact each other (without the sheet of shielding material 102 between the layers 518, 520) and/or by connection through interstices in the sheet of shielding material 102.

In the particular embodiment of FIG. 5, the sheet of shielding material 102 is illustrated closer to the upper surface 110 than the lower surface 112. The sheet of shielding material 102 may, however, be located at any place between or at the upper surface 110 and the lower surface 112. For example, as will be seen below in FIGS. 6 and 7, the sheet of shielding material 102 in some embodiments may be located at about the middle (vertically) of the EMI shielding, thermally-conductive interface assembly 600.

The sheet of shielding material 102 may extend to various lengths and/or widths relative to the thermal interface material 108. As illustrated in FIGS. 2, 3, and 5, the sheet of shielding material 102 is coextensive with (e.g., is the same size, extends to the same border, etc.) the thermal interface material 108. The sheet of shielding material 102 may, however, be larger and/or smaller in one or more dimensions (e.g., length and/or width) than the thermal interface material 108 (as, for example, illustrated by FIG. 7 described below).

Referring now to FIGS. 6 and 7, there is shown another exemplary embodiment of a EMI shielding, thermally-conductive interface assembly 600 embodying one or more aspects of the present disclosure. As shown in exploded view in FIG. 6, the EMI shielding, thermally-conductive interface assembly 600 may include a sheet of shielding material 602 (e.g., electrically-conductive fabric, etc.) having first and second sides 604, 606. The assembly 600 includes a first layer of thermal interface material 608 (e.g., gap filler, thermally-conductive polymer, thermally-conductive polymer with fillers therein, other suitable thermal interface materials such as those disclosed hereinafter, etc.) and a second layer of thermal interface material 622. The sheet of shielding material 602 is disposed between the first and second layers of thermal interface material 608, 622, with the first layer of thermal interface material 608 adjacent the first side 604 of the sheet of shielding material 602 and the second layer of thermal interface material 622 adjacent the second side 606 of the sheet of shielding material 602.

The sheet of shielding material 602 may extend to various lengths and/or widths relative to the layers of thermal interface material 608, 622. As illustrated in FIG. 7, the sheet of shielding material 602 is coextensive with (e.g., is the same size, extends to the same border, etc.) the first and second layers of thermal interface material 608, 622. The sheet of shielding material 602 may, however, be larger and/or smaller in one or more dimensions (e.g., length and/or width) than the layers of thermal interface material 608, 622 (as, for example, illustrated by the size relationship of the sheet of shielding material 102 relative to the thermal interface material 108 in FIGS. 2, 3 and 5).

In the particular embodiment of FIGS. 6 and 7, the sheet of shielding material 602 is illustrated centered between, the first and second layers of thermal interface material 608, 622. The sheet of shielding material 602 may, however, be disposed at any point between upper and lower surfaces 624, 626 of the assembly 600. For example, the assembly 600 may be constructed first as the EMI shielding, thermally-conductive interface assembly 400 or 500 in FIGS. 4 and 5 and a second layer of thermal interface material may then attached, bonded, etc. to the EMI shielding, thermally-conductive interface assembly 400 or 500.

In various embodiments, the layers of thermal interface material 608, 622 are formed from the same thermal interface material. Alternative embodiments, however, may include a different thermal interface material along the first side 604 of the sheet of shielding material 602, than the thermal interface material along the second side 606 of the sheet of shielding material 602. That is, the first and second layers 608, 622 may be formed from different thermal interface materials (e.g., different thermally-conductive polymers, different types of thermal interface materials, etc.) in some embodiments, or they may be formed from the same thermal interface material in other embodiments. In either case, a wide variety of materials may be used for the thermal interface material, including the materials disclosed herein. For example, gap filler may be the thermal interface material disposed along both of the first and second sides 604, 606 of the sheet of shielding material 602. As another example, gap filler may be the thermal interface material disposed along only one of the sides 604 or 606 of the sheet of shielding material 602, and thermal phase change material may be the thermal interface material disposed along the other side 604 or 606 of the sheet of shielding material 602.

In addition, the layers 608, 622 may have about the same thickness or they may have different thicknesses. For example, some embodiments may include a first layer 608 thicker than the outer layer 622, or vice versa.

In any one or more of the embodiments disclosed herein, the sheet of shielding material (e.g., 102, 602, etc.) may include a conductive (e.g., metalized, etc.) fabric such as Flectron™, commercially available from Laird Technologies of St. Louis, Mo. Alternative materials may be used in other embodiments.

The EMI shielding, thermally-conductive interface assemblies discussed herein may be made by any suitable process. For example, after manufacturing a thermal interface material, but before the material has fully cured set, hardened, etc., the material may be formed, etc. into sheets of material by calendaring the thermal interface material between a liner sheet and a sheet of shielding material to form, for example, a EMI shielding, thermally-conductive interface assembly like that in FIG. 2, 3, or 5. The nip (or gap) between a series of heated rollers may be set to the desired thickness of the final EMI shielding, thermally-conductive interface assembly. The thermal interface material may then be run through the rollers to form a pad with a thickness as determined by the gap between the rollers. Simultaneously, a liner sheet and a sheet of shielding material may be run through the rollers on either side of the thermal interface material resulting in a finished EMI shielding, thermally-conductive interface assembly that includes a release liner on one side. The release liner(s) may be any suitable release liner, for example, Mylar liners. Alternatively, the release liner may only be located on both sides of the EMI shielding, thermally-conductive interface assembly, or there may be no release liner applied to the EMI shielding, thermally-conductive interface assembly. A EMI shielding, thermally-conductive interface assembly produced as described above may be used as is or may be further processed to attach another layer of thermal interface material on the opposite side of the sheet of shielding material as the initial layer of thermal interface material in the same manner discussed above (e.g., to produce a EMI shielding, thermally-conductive interface assembly as in FIG. 7).

In another example, a EMI shielding, thermally-conductive interface assembly may be produced by preparing an appropriate thermal interface material and (while the thermal interface material is uncured and has a slurry-like consistency) dipping, dragging, pulling, etc. a sheet of shielding material through the thermal interface material. The sheet of shielding material (now coated with a thermal interface material) may then be calendared as discussed above and cured to produce a EMI shielding, thermally-conductive interface assembly having a sheet of shielding material within a thermal interface material.

Alternatively, a EMI shielding, thermally-conductive interface assembly may be produced by calendaring layers of thermal interface material on opposite sides of a sheet of shielding material at the same time. In such a process, one, two or no liners may also be applied to the EMI shielding, thermally-conductive interface assembly being processed. In yet other embodiments, an EMI mesh or other EMI shielding material may be dipped into a trough of polymer and filler liquid, which is then drawn up to a tower to cure.

EMI shielding, thermally-conductive interface assemblies disclosed herein may additionally, or alternatively, include an adhesive layer on one or both sides of the assembly for mechanical attachment to a component with which the assembly will be used, a heat sink, etc. Alternative embodiments do not include any adhesive layer. In such alternative embodiments, the thermal interface material may be naturally tacky or inherently adhesive. In further embodiments, the thermal interface material may be neither naturally or inherently tacky and/or the EMI shielding, thermally-conductive interface assembly may also not include any adhesive or other bonding means.

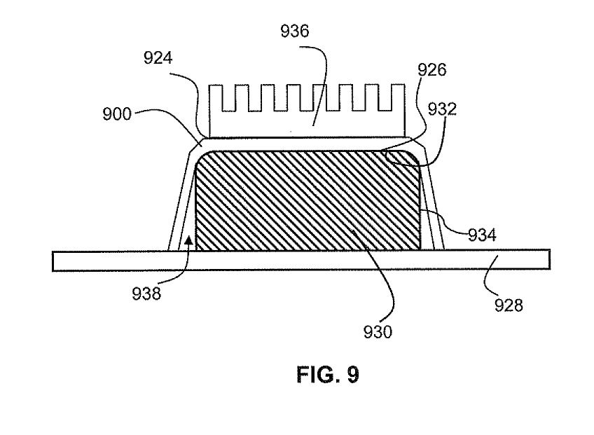

FIG. 8 illustrates another exemplary embodiment of a EMI shielding, thermally-conductive interface assembly 800 shown in connection with a circuit board 828 having an electronic component 830 mounted thereon. In some embodiments, the EMI shielding, thermally-conductive interface assembly 800 may be used for covering multiple electronic components on a circuit board.

The EMI shielding, thermally-conductive interface assembly 800 may be any of the assemblies disclosed herein (e.g., 200, 300, 500, 600, etc.). The EMI shielding, thermally-conductive interface assembly 800 includes at least a sheet of shielding material attached to a thermal interface material. For the sake of clarity, the various layers of the EMI shielding, thermally-conductive interface assembly 800 are not separately illustrated in FIG. 8.

A lower surface 826 of the EMI shielding, thermally-conductive interface assembly 800 contacts an upper surface 832 and sides 834 of the electronic component 830. The thermal interface material of the assembly 800 permits thermal transfer from the upper surface 832 (and the sides 834) to an upper surface 824 of the assembly 800. The heat transferred to the upper surface 824 may be directly dissipated into surrounding air by convection (as in FIG. 8) or may be directly conducted to a heat sink attached to the upper surface 824 (such as, for example, heat sink 936 in FIG. 9).

As illustrated in FIG. 8, the shielding material in the assembly 800 surrounds the upper surface 832 and the sides 834 of the electronic component 830. By so surrounding the electronic component 830 with the shielding material, EMI is limited (shielded, restricted, reduced, etc.) from transmission to and/or from the electronic component 830.

Direct contact with all exposed surfaces of an electronic component is not required for EMI reduction purposes (although it may be beneficial or required for thermal transfer purposes in some instances). Accordingly, FIG. 9 illustrates another exemplary embodiment of a EMI shielding, thermally-conductive interface assembly 900 embodying one or more aspects of the present disclosure. In this particular example, the assembly 900 is shown in connection with a circuit board 928 having an electronic component 930 mounted thereon.

The EMI shielding, thermally-conductive interface assembly 900 may be any of the assemblies disclosed herein (e.g., 200, 300, 500, 600, etc.). The EMI shielding, thermally-conductive interface assembly 900 includes at least a sheet of shielding material attached to a thermal interface material. For the sake of clarity, the various layers of the EMI shielding, thermally-conductive interface assembly 900 are not separately illustrated in FIG. 9.

A lower surface 926 of the assembly 900 contacts an upper surface 932 of the electronic component 930. A heat sink 936 is thermally coupled to an upper surface 924 of the assembly 900. The thermal interface material of the EMI shielding, thermally-conductive interface assembly 900 material permits thermal transfer from the upper surface 932 to the upper surface 924 of the assembly 900 and into the heat sink 936 for dissipation into surrounding air by convection.

The lower surface 926 of the assembly 900 does not contact all (and in some embodiments may not contact any) of sides 934 of the electronic component 930 and there are gaps 938 between the sides 934 of the electronic component 930 and the lower surface 926 of the assembly 900. The assembly 900 may be referred to as being draped over the electronic component 930. In such a configuration, the shielding material in the assembly 900 surrounds the electronic component 930 even if it is not in contact with all surfaces of the electronic component 930. By so surrounding the electronic component 930 with the shielding material, EMI is limited (shielded, restricted, reduced, etc.) from transmission to and/or from the electronic component 930.

As noted above, a wide variety of materials may be used for any one or more thermal interface materials in embodiments disclosed herein. Preferably, a thermal interface material is formed from materials, which are compliant or conformable, have generally low thermal resistance and generally high thermal conductivity, and which are better thermal conductors and have higher thermal conductivities than air alone.

In some embodiments, the thermal interface material is a gap filler (e.g., T-flex™ gap fillers from Laird Technologies, etc.). By way of example, the gap filler may have a thermal conductivity of about 3 Watts per meter Kelvin (W/mK). By way of further example, the gap filler may have a thermal conductivity of about 1.2 W/mK. Additional exemplary gap fillers may have a thermal conductivity of about 6 W/mK. In still further embodiments, the thermal interface material is a thermally-conductive insulator (e.g., T-gard™ 500 thermally-conductive insulators from Laird Technologies). A thermal interface material used in exemplary embodiments may have a thermal conductivity of at least 0.5 Watts per meter per Kelvin (W/mK) or more (e.g., a thermal conductivity of 0.5 W/mK, 0.7 W/mK, 1.2 W/mK, 2.8 W/mK, 3.0 W/mK, 6.0 W/mK, etc.). The disclosure of these particular values (0.5, 0.7, 1.2, 2.8, 3.0, 6.0) and range (0.5 or higher) for thermal conductivity are not exclusive of other values and ranges of values that may be useful in one or more of the examples disclosed herein.

In other embodiments, the thermal interface material may comprise gap filler on one side of the shielding material (which may also be heat-spreading material) and a thermal phase change material (e.g., T-pcm™ 580S series phase change material from Laird Technologies, Inc., etc.) on the other side of the shielding material. In such embodiments, a thermal phase change material may be used, by way of example, that has a phase change softening point of about 50° Celsius, an operating temperature range of about −40° Celsius to about 125° Celsius, and a thermal conductivity of about 3.8 W/mK. Other thermal phase change materials may also be used.

Further embodiments may include a thermally-conducting electrically-isolating compliant material with or without fiberglass reinforcement on both sides of the shielding material. In such embodiments, the EMI shielding, thermally-conductive interface assembly or structure may be EMI shielding and electrically conductive on the inside, while also being an electrically insulating thermal interface material on the outside.

TABLE 1 below lists various exemplary thermal interface materials that may be used as a thermal interface material in any one or more exemplary embodiments described and/or shown herein. These exemplary materials are commercially available from Laird Technologies, Inc. of Saint Louis, Mo., and, accordingly, have been identified by reference to trademarks of Laird Technologies, Inc. This table and the materials and properties listed therein are provided for purposes of illustration only and not for purposes of limitation.

TABLE 1

| | | | | | Pressure of |
|---|---|---|---|---|---|
| | | | | | Thermal |
| | | | Thermal | Thermal | Impedance |
| | Construction | | Conductivity | Impedance | Measurement |
| Name | Composition | Type | [W/mK] | [° C.-cm²/W] | [kPa] |
| T-flex ™ 6100 | Boron nitride | Gap | 3.0 | 7.94 | 69 |
| | filled silicone | Filler | | | |
| | elastomer | | | | |
| T-pli ™ 210 | Boron nitride | Gap | 6 | 1.03 | 138 |
| | filled, silicone | Filler | | | |
| | elastomer, | | | | |
| | fiberglass | | | | |
| | reinforced | | | | |
| T-grease ™ | Silicone- | Thermal | 1.2 | 0.138 | 348 |
| | based grease | Grease | | | |
| | or non- | | | | |
| | silicone | | | | |
| | based grease | | | | |
| T-flex ™ | Silicone free | Gap | 2.8 | 1.94 | 69 |
| SF620 | ceramic filled | Filler | | | |
| | elastomer | | | | |
| T-flex ™ | Ceramic filled | Gap | 1.1 | 16.19 | 69 |
| 280V0 | silicone | Filler | | | |
| | elastomer | | | | |
| T-flex ™ | Ceramic filled | Gap | 1.8 | 6.78 | 69 |
| HR440 | silicone | Filler | | | |
| | elastomer | | | | |
| T-flex ™ 740 | Particulate | Gap | 5.0 | 1.81 | 69 |
| | filled silicone | Filler | | | |
| | elastomer | | | | |
| T-flex ™ | Particulate | Gap | 3.0 | 6.45 | 69 |
| HR6100 | filled silicone | Filler | | | |
| | elastomer | | | | |

In addition to the examples listed in the table above, other thermal interface materials can also be used, which are preferably better than air alone at conducting and transferring heat. Other exemplary materials include compliant or conformable silicone pads, non-silicone based materials (e.g., non-silicone based gap filler materials, elastomeric materials, etc.), polyurethane foams or gels, thermal putties, thermal greases, etc. In some embodiments, one or more conformable thermal interface pads are used having sufficient conformability for allowing a pad to relatively closely conform to the size and outer shape of an electronic component when placed in contact with the electronic component.

TABLE 2 below lists various exemplary metalized fabrics that may be used as a sheet of shielding material in any one or more exemplary embodiments described and/or shown herein. These exemplary materials are commercially available from Laird Technologies, Inc. of Saint Louis, Mo., and, accordingly, have been identified by reference to trademarks of Laird Technologies, Inc. This table and the materials and properties listed therein are provided for purposes of illustration only and not for purposes of limitation.

TABLE 2

| | | | | Surface | Far-field | Far-field |
|---|---|---|---|---|---|---|
| | | | Thickness | resistivity | Shielding | Shielding |
| Name | Substrate | Metal | [microns] | [ohms/square] | [dB @ 100 MHz] | [dB @ 1 GHz] |
| Flectron ™ | Polyester | Nickel/Copper | 152 | ≦0.07 | 80 | 80 |
| | Taffeta | | | | | |
| Flectron ™ | Nylon Ripstop | Nickel/Copper | 127 | ≦0.07 | 85 | 75 |
| Flectron ™ | Polyester | Nickel/Copper | 203 | ≦0.1 | 70 | 60 |
| | Knitted Mesh | | | | | |

Exemplary embodiments (e.g., 200, 300, 500, 600, etc.) disclosed herein may be used with a wide range of electronic components, heat sources, heat-generating components, heat sinks, among others. By way of example only, thermal interface assemblies disclosed herein may be used with memory modules or devices (e.g., random access memory (RAM) modules or devices, double-data-rate (DDR) memory modules or devices (e.g., DDR1, DDR2, DDR3, DDR4, DDR5, etc.), flash memory dual inline memory module (FMDIMM) memory modules or devices, synchronous dynamic random access memory (SDRAM) memory modules or devices, etc.), printed circuit boards, high frequency microprocessors, central processing units, graphics processing units, laptop computers, notebook computers, desktop personal computers, computer servers, thermal test stands, portable communications terminals (e.g., cellular phones, etc.), etc. Accordingly, aspects of the present disclosure should not be limited to use with any one specific type of end use, electronic component, part, device, equipment, etc.

Numerical dimensions and the specific materials disclosed herein are provided for illustrative purposes only. The particular dimensions and specific materials disclosed herein are not intended to limit the scope of the present disclosure, as other embodiments may be sized differently, shaped differently, and/or be formed from different materials and/or processes depending, for example, on the particular application and intended end use.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

In addition, the disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter. The disclosure of a first value and a second value for a given parameter can be interpreted as disclosing that any value between the first and second values could also be employed for the given parameter. Similarly, it is envisioned that disclosure of two or more ranges of values for a parameter (whether such ranges are nested, overlapping or distinct) subsume all possible combination of ranges for the value that might be claimed using endpoints of the disclosed ranges.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. An EMI shielding, thermally-conductive interface assembly comprising a sheet of shielding material sandwiched between first and second layers of thermal interface material and configured to restrict transmission of electromagnetic interference through the EMI shielding, thermally-conductive interface assembly.

2. The assembly of claim 1, wherein the sheet of shielding material comprises one or more of:
an electrically-conductive fabric;
an electrically-conductive mesh;
a metal foil;
a metal foil having one or more openings therethrough;
a thin, flexible metal layer;
a thin, flexible metal layer having one or more openings therethrough; or
a flexible graphite sheet.

3. The assembly of claim 1, wherein the sheet of shielding material is embedded within the thermal interface material.

4. The assembly of claim 1, wherein the first layer of the thermal interface material is bonded to the second layer of the thermal interface material.

5. The assembly of claim 1, wherein:
the sheet of shielding material includes first and second sides and one or more openings therebetween; and
at least a portion of the thermal interface material is disposed within the one or more openings, which helps mechanically bond the first and second layers of thermal interface material to the sheet of shielding material and/or helps provide a thermally-conductive pathway between the first and second sides of the sheet of shielding material.

6. The assembly of claim 1, wherein:
the sheet of shielding material comprises an electrically-conductive fabric having first and second sides and a plurality of interstices therebetween; and
at least a portion of the thermal interface material is disposed within one or more of the interstices, which helps mechanically bond the first and second layers of thermal interface material to the electrically-conductive fabric and/or helps provide a thermally-conductive pathway between the first and second sides of the electrically-conductive fabric.

7. The assembly of claim 1, wherein the first layer is formed from a different thermal interface material than the second layer.

8. The assembly of claim 1, wherein the thermal interface material comprises one or more of:
a thermally-conductive polymer;
a thermally-conductive compliant material;
a thermal interface/phase change material.
a gap filler;
a thermal grease;
elastomer filled with thermally-conductive materials formed from metal particles, graphite particles, and/or ceramic particles;
a thermally-conductive electrically-isolating compliant material including fiberglass reinforcement;
a thermally-conductive electrically-isolating compliant material including fiberglass reinforcement; or
any combination thereof.

9. The assembly of claim 1, wherein the sheet of shielding material comprises a metalized fabric.

10. A device including at least one heat source and the assembly of claim 1 positioned relative to the at least one heat source such that a thermally-conductive heat path is defined from the at least one heat source through the assembly and such that transmission of EMI to and/or from the at least one heat source is restricted.

11. The device of claim 10, further comprising a heat sink such that the thermally-conductive heat path is defined from the at least one heat source through the assembly to the heat sink.

12. The device of claim 10, wherein the at least one heat source includes at least two heat sources, and wherein the assembly is positioned relative to the at least two heat sources such that a thermally-conductive heat path is defined from the at least two heat sources through the assembly and such that transmission of EMI to and/or from the at least two heat sources is restricted.

13. An EMI shielding, thermally-conductive interface assembly comprising a thermal interface material and a sheet of shielding material embedded within the thermal interface material.

14. The assembly of claim 13, wherein the sheet of shielding material comprises one or more of:
an electrically-conductive fabric;
an electrically-conductive mesh;
a metal foil;
a metal foil having one or more openings therethrough;
a thin metal layer;
a thin metal layer having one or more openings therethrough; or
a flexible graphite sheet.

15. The assembly of claim 13, wherein the sheet of shielding material is embedded within the thermal interface material such that the sheet of shielding material is fully encapsulated within the thermal interface material.

16. The assembly of claim 13, wherein the sheet of shielding material is sandwiched between first and second layers of the thermal interface material respectively defining upper and lower surfaces of the assembly.

17. The assembly of claim 13, wherein:
the sheet of shielding material comprises an electrically-conductive fabric having first and second sides and a plurality of interstices therebetween; and
at least a portion of the thermal interface material is disposed within one or more of the interstices, which helps mechanically bond the first and second layers of thermal interface material to the electrically-conductive fabric and/or helps provide a thermally-conductive pathway between the first and second sides of the electrically-conductive fabric.

18. The assembly of claim 13, wherein the thermal interface material comprises one or more of:
a thermally-conductive polymer;
a thermally-conductive compliant material;
a thermal interface/phase change material.
a gap filler;
a thermal grease;
elastomer filled with thermally-conductive materials formed from metal particles, graphite particles, and/or ceramic particles;
a thermally-conductive electrically-isolating compliant material including fiberglass reinforcement;
a thermally-conductive electrically-isolating compliant material including fiberglass reinforcement; or
any combination thereof.

19. The assembly of claim 13, wherein the sheet of shielding material comprises a metalized fabric.

20. A device including at least one heat source and the assembly of claim 13 positioned relative to the at least one heat source such that a thermally-conductive heat path is defined from the at least one heat source through the assembly and such that transmission of EMI to and/or from the at least one heat source is restricted.

21. The device of claim 20, further comprising a heat sink such that the thermally-conductive heat path is defined from the at least one heat source through the assembly to the heat sink.

22. The device of claim 20, wherein the at least one heat source includes at least two heat sources, and wherein the assembly is positioned relative to the at least two heat sources such that a thermally-conductive heat path is defined from the at least two heat sources through the assembly and such that transmission of EMI to and/or from the at least two heat sources is restricted.

23. The assembly of claim 13, wherein the sheet of shielding material embedded within the thermal interface material is an electrically-conductive fabric having first and second sides and a plurality of interstices at least some of which are impregnated with the thermal interface material.

24. The assembly of claim 13, wherein the sheet of shielding material embedded within the thermal interface material is an electrically-conductive fabric having a tubular configuration with a hollow interior portion that includes at least a portion of the thermal interface material.

25. A method relating to heat dissipation from and EMI shielding for at least one generating component of a circuit board, the method comprising positioning an assembly, which comprises a sheet of shielding material embedded in a thermal interface material, such that a thermally-conductive heat path is defined from the at least one heat generating component through the thermal interface material and the sheet of shielding material, and such that transmission of EMI to and/or from the heat generating component is restricted.

26. A method for making an EMI shielding, thermally-conductive interface assembly having an upper surface and a lower surface, the method comprising applying thermal interface material to an electrically-conductive fabric having a plurality of interstices such that the electrically-conductive fabric is embedded in the thermal interface material and such that at least a portion of the thermal interface material is disposed within at least one of the plurality of interstices to provide a thermally-conductive path between the upper surface and the lower surface and restrict transmission of EMI through the thermally-conductive interface assembly.
